(19) United States
(12) Patent Application Publication
(10) Pub. No.: US 2013/0213698 A1
(43) Pub. Date: Aug. 22, 2013

(54) HOLDER FOR SEMICONDUCTOR PACKAGE

(71) Applicants: Jeff BIAR, New Taipei City (TW); Chih-Kung Huang, New Taipei City (TW); Ming-Ching Wu, New Taipei City (TW)

(72) Inventors: Jeff BIAR, New Taipei City (TW); Chih-Kung Huang, New Taipei City (TW); Ming-Ching Wu, New Taipei City (TW)

(73) Assignee: DOMINTECH CO., LTD, New Taipei City (TW)

(21) Appl. No.: 13/540,967

(22) Filed: Jul. 3, 2012

(30) Foreign Application Priority Data
Feb. 21, 2012 (TW) 101203103

(51) Int. Cl. H05K 1/03

(52) U.S. Cl. 174/255

(57) ABSTRACT

A holder includes a main body on which a plurality of circuit lines are laid out. The main body is integrally molded from a plastic material and can be formed thereon with a circuit layout by a specific process, such as a laser activated and chemical plating process. The main body includes a chamber having an opening formed at the top side of the main body, a base surface, and a stepped wall. Each of the circuit lines is arranged on the stepped wall of the chamber stereoscopically. Thus, the holder does not need to make a hole running therethrough to reach electrical connection between surfaces of different heights. Besides, the circuit lines are arranged stereoscopically, so they can extend to the top and bottom sides of the holder. Therefore, the holder can be applied to not only the traditional package but an upside-down package.

### BACKGROUND OF THE INVENTION

1. Field of the Invention

The present invention relates generally to a semiconductor package, and more particularly, to a holder for a semiconductor package, which is integrally molded from a plastic material and has a chamber with a stepped wall, and a plurality of surface circuit lines laid out in a three-dimensional manner.

2. Description of the Related Art

U.S. Pat. No. 4,833,102 disclosed a ceramic base for a semiconductor chip package. As shown in FIG. 3 of this patent, the ceramic base includes a cavity formed at a center thereof and provided with a bottom side for supporting a chip, and a cavity shoulder having metallization disposed thereon and running through the lateral wall of the base for connection with external metal pins. The chip is electrically connected with the metallization via a plurality of bonding wires, such that the chip is electrically connected with the external metal pins. The primary drawback of this conventional ceramic base lies in that when the metallization disposed on the cavity shoulder is connected with the external metal pins, as indicated by the dotted lines in the aforesaid FIG. 3, it is necessary to make a hole running through the lateral wall of the ceramic base, being a high-cost and time-consuming processing procedure.

To improve the aforesaid drawback, U.S. Pat. No. 5,200,367 disclosed a holder made by double molding for semiconductor package. The holder though does not need the processing procedure of making a hole running through the lateral wall thereof, but it must tight fit the lead frame structurally, as shown in FIG. 3f of this patent, so the electrical connection between the internal chip and the external components can only be available through the lateral wall of the holder, thus limiting the applicable span of the package using the aforesaid holder. In other words, the electrical connection between the internal chip and the external circuit motherboard cannot be available through the top side or bottom side of the holder. Besides, such holder needs to be made by double molding, so the production cost is still high.

### SUMMARY OF THE INVENTION

The primary objective of the present invention is to overcome the above-mentioned disadvantages encountered in the aforesaid base and holder of the prior art and to provide a holder for a semiconductor package, wherein the holder is made of a specific plastic material by one-time molding and three-dimensional circuit lines can be formed on the surface of the holder. Thus, it needs neither to make a hole running through the holder for electrical connection between inside and outside of the holder nor to fit the conventional lead frame for electrical connection.

The secondary objective of the present invention is to provide a holder for a semiconductor package, wherein the holder includes three-dimensional circuit lines, such that the applicable span of the holder is broader, e.g. the holder can be designed in such a way that the electrical connection with the circuit motherboard can be available through the top or bottom side of the holder.

The foregoing objectives of the present invention are attained by a holder comprising a main body and a plurality of circuit lines arranged on the main body. The main body is integrally molded from a specific plastic material, on a product of which a circuit layout is formable by a predetermined process, such as a laser activated and chemical plating process. The main body includes a top side, a bottom side, an external side located between the top and bottom sides, and a chamber. The chamber has an opening formed at the top side of the main body, a base surface, and a first step surface. A height difference exists between the first step surface and the top side of the main body and between the first step surface and the base surface, such that a first internal lateral surface is defined between the first step surface and the base surface and a second internal lateral surface is defined between the first step surface and the top side of the main body. Each of the circuit lines extends from the first step surface along the second internal lateral surface to the top side of the main body.

As known from the above, the holder of the present invention includes the three-dimensional circuit lines arranged on the surfaces of different height, so it does not need to make a hole running through the holder for electrical connection between the surfaces of different height. Besides, the holder of the present invention only needs one-time molding and the circuit lines on the surface of the holder can be configured extending to the top and bottom sides of the holder, so the holder provided by the present invention is broader than the prior art in applicable span.

In addition, the chamber is not limited to one step surface but can have two or more step surfaces as per the actual requirement. Further, a through hole can be formed between the base surface of the chamber and the bottom side of the main body, such that the holder can be used for packaging optical control chip.

### BRIEF DESCRIPTION OF THE DRAWINGS

FIG. 1 is a sectional view of a holder according to a first preferred embodiment of the present invention.

FIG. 2 is a sectional view showing that the holder of the first preferred embodiment of the present invention is applied to a semiconductor chip packaging.

FIG. 3 is a sectional view of a holder according to a second preferred embodiment of the present invention.

FIG. 4 is a sectional view showing that the holder of FIG. 3 is applied to a semiconductor chip package.

FIG. 5 is a sectional view of a holder according to a third preferred embodiment of the present invention.

FIG. 6 is a sectional view showing that the holder of FIG. 5 is applied to a semiconductor chip packaging.

FIG. 7 is a sectional view of a holder according to a fourth preferred embodiment of the present invention.

FIG. 8 is a sectional view showing the holder of FIG. 7 is applied to a semiconductor chip packaging.

### DETAILED DESCRIPTION OF PREFERRED EMBODIMENTS

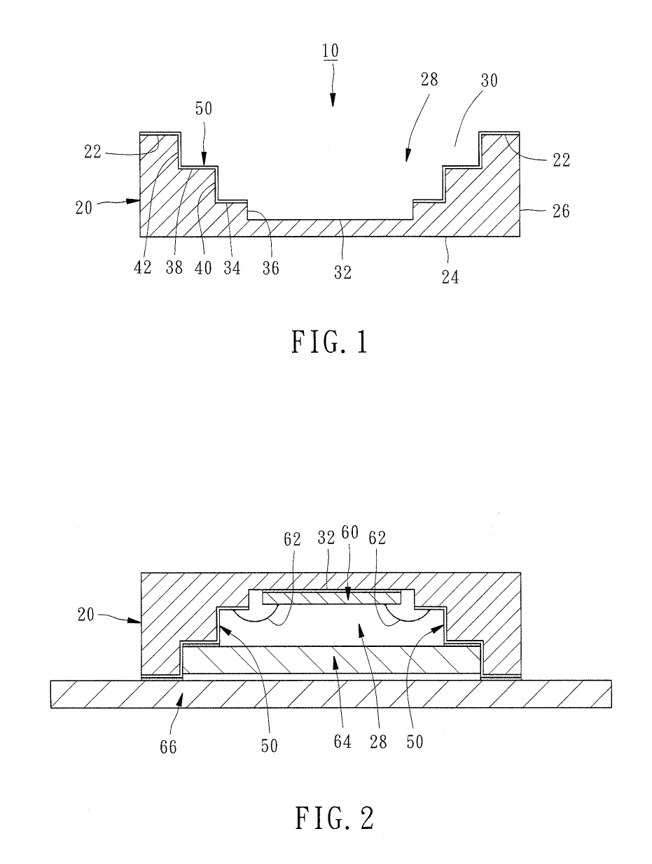

Referring to FIGS. 1-2, a holder, denoted by a reference numeral 10, for a semiconductor package in accordance with a first preferred embodiment of the present invention is basically a cuboid plastic-molded member, on the surface of which copper circuit lines can be formed by a laser activated and chemical plating process, such as the so-called LPKF-LDS process. The laser-activatable plastic material for molding the holder 10 is commercially available, such as the one sold by a German company, LPKF Laser & Electronics AG. Since such material and the laser activated and chemical plating process by which the copper circuit lines are formed on the surface of an object made of the same material belong to the prior art, detailed recitation in this regard is skipped. The holder 10 is composed of a main body 20 and a plurality of circuit lines 50 arranged on the main body 20. The detailed descriptions and operations of these elements as well as their interrelations are recited in the respective paragraphs as follows.

The main body 20 includes a top side 22, a bottom side 24, an external side 26, and a chamber 28 having an opening 30 formed at a center of the top side 22. The chamber 28 is provided with a base surface 32, a first step surface 34, and a second step surface 38. A height difference exists between the first step surface 34 and the base surface 32, such that a first internal lateral surface 36 is defined between the first step surface 34 and the base surface 32. A height difference exists between the second step surface 38 and the first step surface 34 and between the second step surface 38 and the top side 22, such that a second internal lateral surface 40 and a third internal lateral surface 42 are respectively defined between the first and second step surfaces 34 and 38 and between the second step surface 38 and the top side 22.

The circuit lines 50 are built up on the surface of the main body 20 and the pattern and number of the circuit lines 50 can be designed subject to actual usage. Specifically, the circuit lines 50 in this embodiment extend from the first step surface 34, vertically through the second internal lateral surface 40, horizontally through the second step surface 38, vertically through the third internal lateral surface 42, and finally to the top side 22.

When the holder 10 is used to package a semiconductor chip 60, as shown in FIG. 2, the chip 60 is adhered to the base surface 32 of the chamber 28 and then electrically connected with the circuit lines 50 via bonding wires 62. Next, a cover member 64 is mounted on the second step surface 38 to seal the chamber 28. When the package is mounted onto a motherboard 66, the package is turned upside down and then attached on the motherboard 66 in such a way that the circuit lines 50 on the top side 22 of the main body 20 are mechanically and electrically connected with the motherboard 66. In this embodiment, the package is turned upside down to make the chip 60 be suspended on the base surface 32 when it is used. This can prevent the chip 60 from influence resulting from environmental stress.

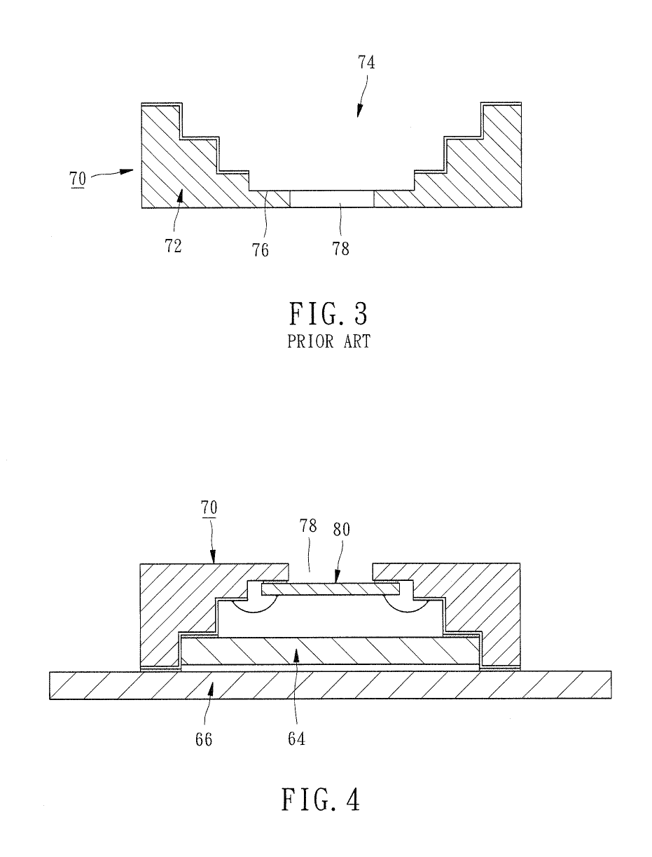

Referring to FIGS. 3-4, a holder, denoted by a reference numeral 70 in the drawings, for a semiconductor package in accordance with a second preferred embodiment of the present invention is configured similar to the holder 10 of the first embodiment, except that the base surface 76 of the chamber 74 of the main body 72 includes a through hole 78 running therethrough. When the package is used, the package is also turned upside down, such that an optical signal can be received by the photo-sensitive chip 80 through the through hole 78.

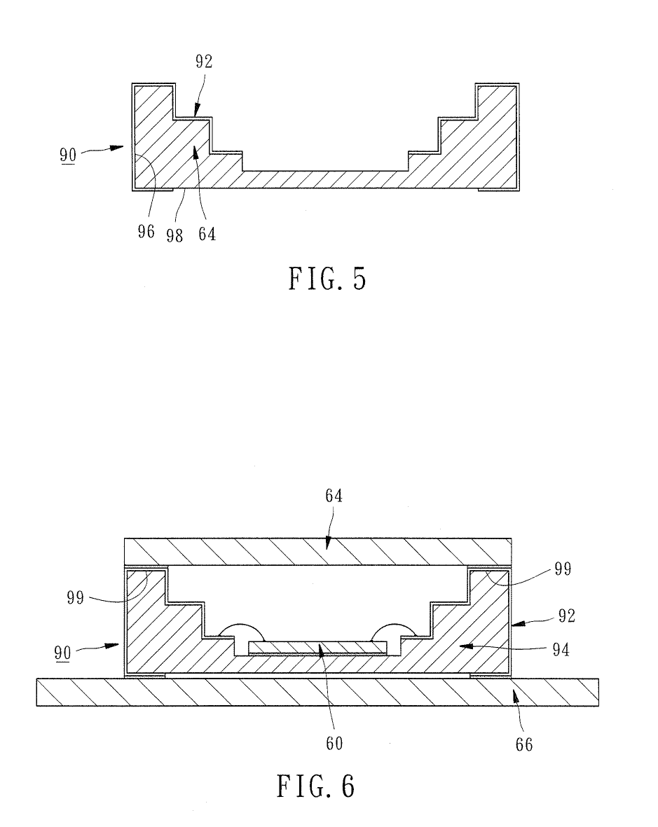

Referring to FIGS. 5-6, a holder 90 for a semiconductor package in accordance with a third preferred embodiment of the present invention is configured similar to the holder 10 of the first embodiment, except that the circuit lines 92 further extend along an external lateral side 96 of the main body 94 to the bottom side 98 and the cover member 64 is covered on the top side 99 of the main body 94. As shown in FIG. 6, the package is mounted onto the motherboard 66 in a way that the circuit lines 92 on the bottom side 98 are connected with the motherboard 66 to enable electrical connection between the motherboard 66 and the chip 60.

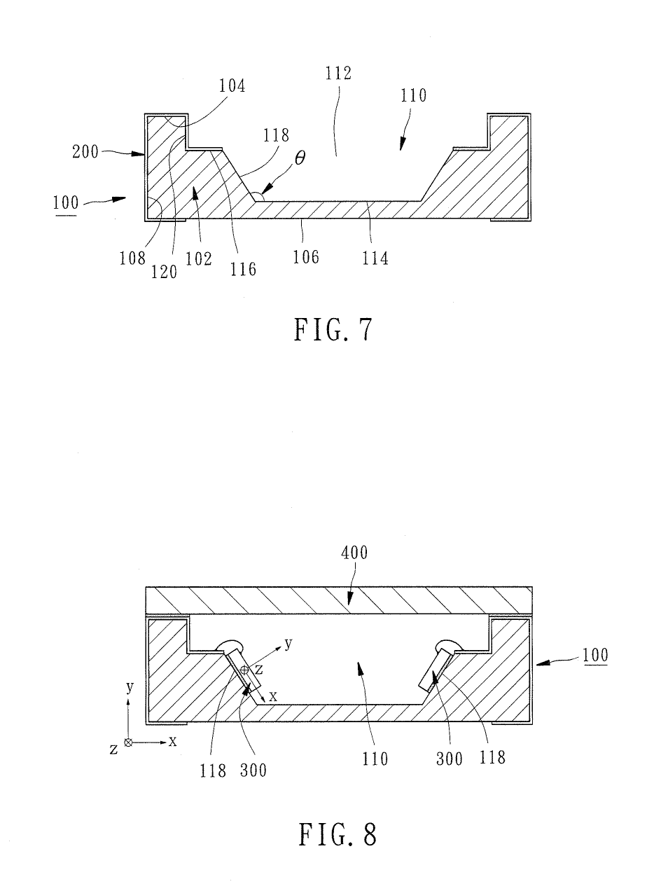

Referring to FIGS. 7-8, a holder 100 for a semiconductor package in accordance with a fourth preferred embodiment of the present invention includes a main body 102 and a plurality of circuit lines 200 arranged on the main body 102.

The main body 102 includes a top side 104, a bottom side 106, an external lateral side 108, and a chamber 110. The chamber 110 is provided with an opening 112 formed at a center of the top side 104, a base surface 114, and a first step surface 116. A height difference exists between the first step surface 116 and the base surface 114 and between the first step surface 116 and the top side 104, such that a first internal lateral surface 118 and a second internal lateral surface 120 are respectively defined between the first step surface 116 and the base surface 114 and between the first step surface 116 and the top side 104. The primary feature of this embodiment lies in that the first internal lateral surface 118 is inclined at an angle θ defined between the first internal lateral surface 118 and the base surface 114 wherein the angle θ is more than 90 degrees. In this embodiment, the angle θ is 135 degrees.

The circuit lines 200 of this embodiment extend from the first step surface 116, vertically through the second internal lateral surface 120, horizontally through the top side 104, vertically through the external lateral side 108, and finally to the bottom side 106.

When the holder 100 is applied to the packaging process, as shown in FIG. 8, a plurality of chips 300 can be adhered to the first lateral surface 118 and then a cover member 400 is covered at the opening 112 of the chamber 110 so as to complete the package. In this way, the chips 300 can acquire the horizontal x-axis component and the vertical y-axis component of a signal.

Although the present invention has been described with respect to specific preferred embodiments thereof, it is in no way limited to the specifics of the illustrated structures but changes and modifications may be made within the scope of the appended claims.

What is claimed is:

1. A holder for a semiconductor package, comprising:
a main body integrally molded from plastic materials, the main body having a top side, a bottom side, an external lateral side located between the top and bottom sides, and a chamber having an opening formed at the top side, a base surface, and a first step surface, wherein a height difference exists between the top side of the main body and the first step surface and between the first step surface and the base surface of the chamber, such that a first internal lateral surface is defined between the first step surface and the base surface and a second internal lateral surface is defined between the top side of the main body and the first step surface; and
a plurality of circuit lines arranged on the main body, each of the circuit lines having a first horizontal portion located on the first step surface, a first vertical portion located on the second internal lateral surface, and a second horizontal portion located on the top side of the main body.

2. The holder as defined in claim 1, wherein the circuit lines are formed by a laser activated and chemical plating process on a surface of the main body.

3. The holder as defined in claim 1, wherein each of the circuit lines comprises a second vertical portion located at the external lateral side of the main body.

4. The holder as defined in claim 2, wherein each of the circuit lines comprises a third horizontal portion located at the bottom side of the main body.

5. The holder as defined in claim 1, wherein the main body comprises a through hole formed through the bottom side of the main body and the base surface of the chamber.

6. The holder as defined in claim 1, wherein the first internal lateral surface is inclined at an angle which is more than 90 degrees and defined between the first internal lateral surface and the base surface of the chamber.

7. A holder for a semiconductor package, comprising:
a main body integrally molded from plastic materials, the main body having a top side, a bottom side, an external lateral side located between the top and bottom sides, and a chamber having an opening formed at the top side, a base surface, a first step surface, and a second step surface, wherein a height difference exists between the first step surface and the base surface such that a first internal lateral surface is defined between the first step surface and the base surface; wherein a height difference exists between the second step surface and the first step surface and between the second step surface and the top side of the main body such that a second internal lateral surface is defined between the second step surface and the first step surface, and a third internal lateral surface is defined between the second step surface and the top side of the main body, and
a plurality of circuit lines arranged on the main body, each of the circuit lines having a first horizontal portion located on the first step surface, a first vertical portion located on the second internal lateral surface, and a second horizontal portion located on the second step surface, a second vertical portion located on the third internal lateral surface, and a third horizontal portion located on the top side of the main body.

8. The holder as defined in claim 7, wherein the circuit lines are formed by a laser activated and chemical plating process on a surface of the main body.

9. The holder as defined in claim 6, wherein each of the circuit lines comprises a third vertical portion located on the external lateral side of the main body.

10. The holder as defined in claim 7, wherein each of the circuit lines comprises a fourth horizontal portion located on the bottom side of the main body.

11. The holder as defined in claim 6, wherein the main body comprises a through hole formed through the bottom side of the main body and the base surface of the chamber.

12. The holder as defined in claim 6, wherein the first internal lateral surface is inclined at an angle which is more than 90 degrees and defined between the first internal lateral surface and the base surface of the chamber.
